(19) United States
(12) Patent Application Publication
(10) Pub. No.: US 2025/0081492 A1
(43) Pub. Date: Mar. 6, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kuei-Lin CHAN, Hsinchu (TW); Wei-Ting YEH, Hsinchu (TW); Fu-Ting YEN, Hsinchu (TW); Yu-Yun PENG, Hsinchu (TW); Keng-Chu LIN, Pingtung (TW)

(21) Appl. No.: 18/240,033

(22) Filed: Aug. 30, 2023

(51) Int. Cl. H01L 29/66; C23C 16/455; H01L 21/02

(52) U.S. Cl. CPC H10D 30/014; C23C 16/45536; C23C 16/45553; H01L 21/02211; H01L 21/02274; H01L 21/0228; H10D 64/017

(57) ABSTRACT

Embodiments of the present disclosure provide semiconductor device structures and methods of forming the same. The method includes removing a first semiconductor layer disposed between a second semiconductor layer and a third semiconductor layer and performing an oxide refill process to form a seamless dielectric material between the second and third semiconductor layers. The oxide refill process includes exposing the second and third semiconductor layers to a silicon-containing precursor at a first flow rate for a first duration to form a monolayer, and exposing the monolayer to an oxygen-containing precursor at a second flow rate for a second duration to form the seamless dielectric material, the second flow rate is about twice to about 20 times the first flow rate, and the second duration is about twice to about 20 times the first duration.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 are perspective views of various stages of manufacturing a semiconductor device structure, in accordance with some embodiments.

FIG. 10-1 is a cross-sectional side view of a portion of the semiconductor device structure of FIG. 10, in accordance with some embodiments.

FIGS. 11A-11D are cross-sectional side views of a portion of the semiconductor device structure of FIG. 10 at various stages of a thermal atomic layer deposition process, in accordance with some embodiments.

FIG. 12 illustrates a chemical structure of a silicon-containing precursor utilized in the thermal atomic layer deposition process, in accordance with some embodiments.

FIG. 13 illustrates various states of a compound formed by the thermal atomic layer deposition process, in accordance with some embodiments.

FIGS. 14-20 are perspective views of various stages of manufacturing the semiconductor device structure, in accordance with some embodiments.

FIG. 15-1 is a cross-sectional side view of a portion of the semiconductor device structure of FIG. 15, in accordance with some embodiments.

FIG. 15-2 is a cross-sectional side view of a portion of the semiconductor device structure of FIG. 15, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide semiconductor device structures and methods of forming the same. In some embodiments, an oxide refill process, such as a thermal horizontal oxide refill (THOR) process is performed to form a seamless dielectric material between vertically adjacent semiconductor layers.

While the embodiments of this disclosure are discussed with respect to nanostructure channel FETs, implementations of some aspects of the present disclosure may be used in other processes and/or in other devices, such as Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

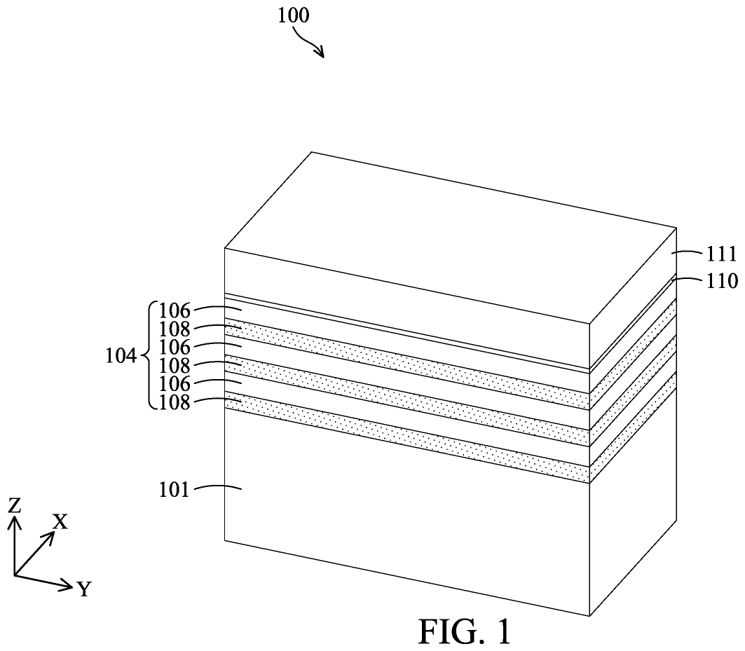

FIGS. 1 to 20 show exemplary processes for manufacturing a semiconductor device structure 100 according to embodiments of the present disclosure. It is understood that additional operations can be provided before, during, and after processes shown by FIGS. 1 to 20, and some of the operations described below can be replaced or eliminated, for additional embodiments of the method. The order of the operations/processes is not limiting and may be interchangeable.

FIGS. 1 to 10 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

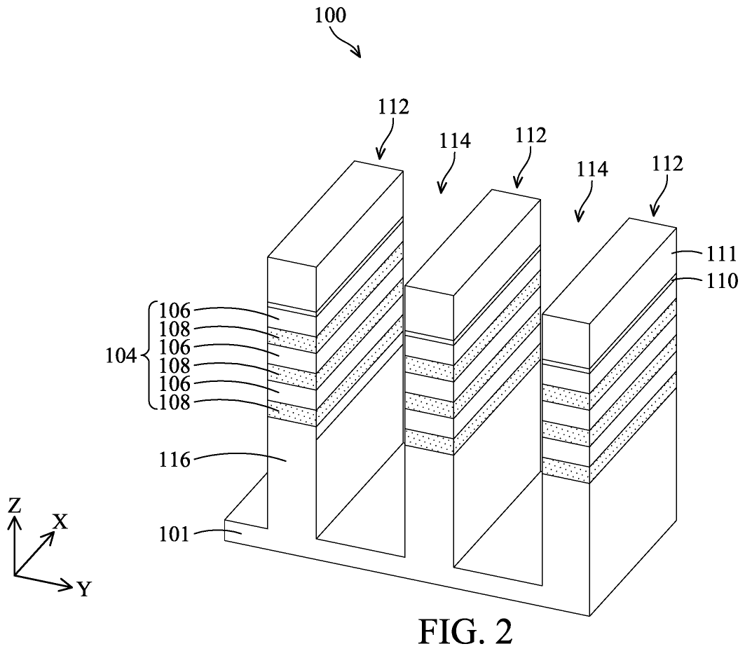

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

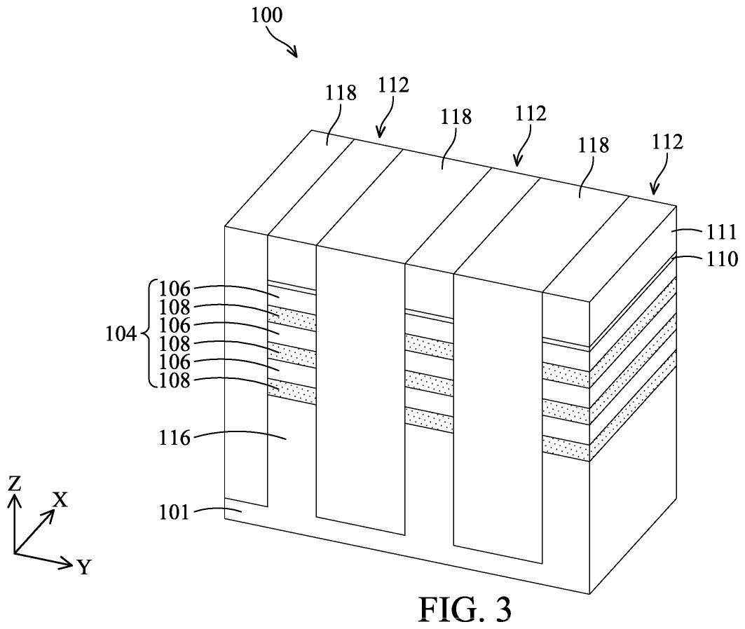

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

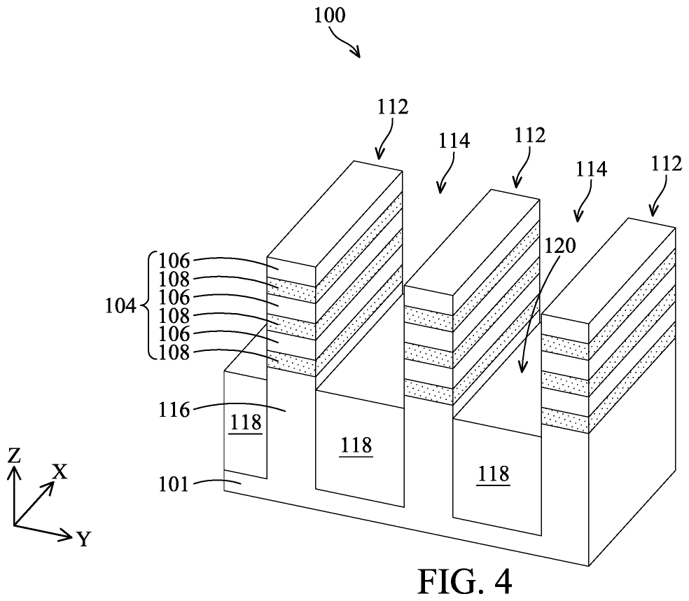

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101. In some embodiments, the isolation regions 120 are the STI. In some embodiments, the oxide layer 110 and the nitride layer 111 are also removed during the recessing of the insulating material 118.

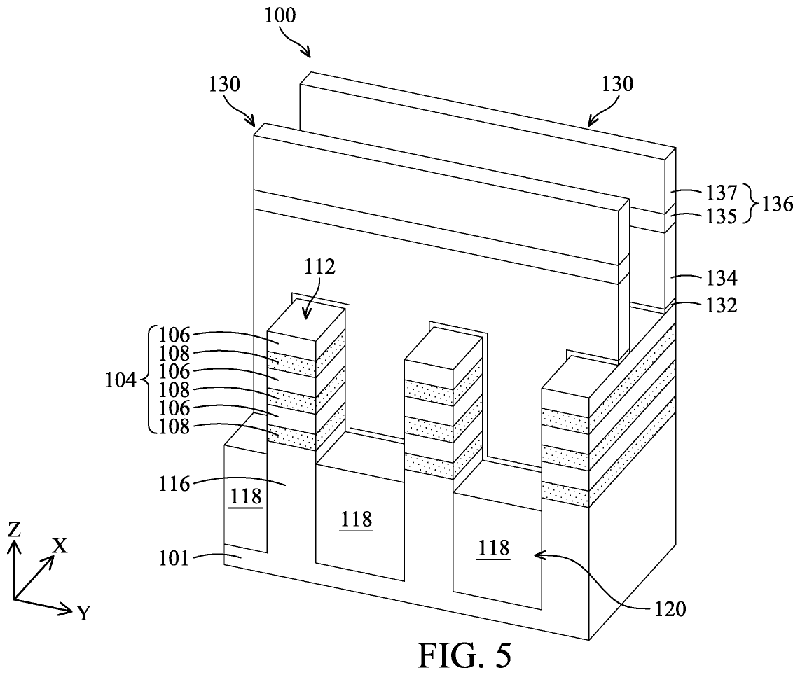

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

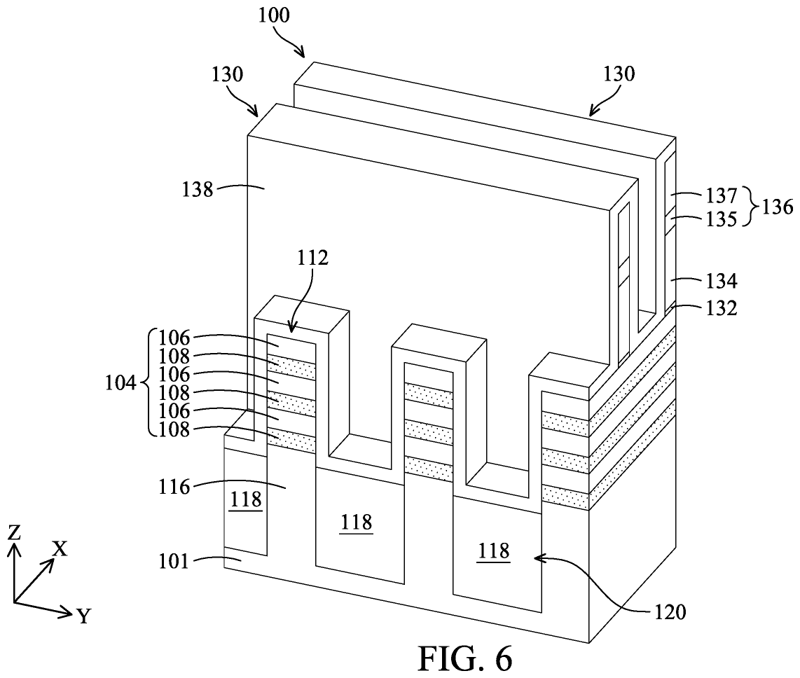

In FIG. 6, a gate spacer layer 138 is formed to cover the sacrificial gate structures 130, the second portions of the fin structures 112, and the second portions of the isolation regions 120. The gate spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the gate spacer layer 138 is formed by a conformal process, such as an atomic layer deposition (ALD) process. In some embodiments, the gate spacer layer 138 has a thickness ranging from about 2 nm to about 10 nm.

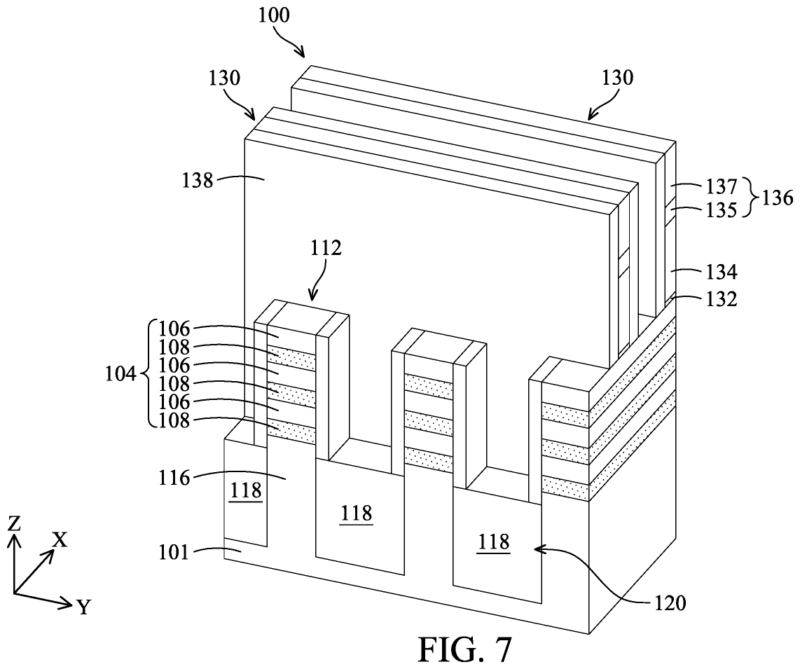

In FIG. 7, an anisotropic etch process is performed to remove horizontal portions of the gate spacer layer 138. The anisotropic etch process may be a selective etch process that does not substantially affect the nitride layer 137, the first semiconductor layer 106, and the isolation region 120. As a result, the second portions of the fin structures 112 are exposed.

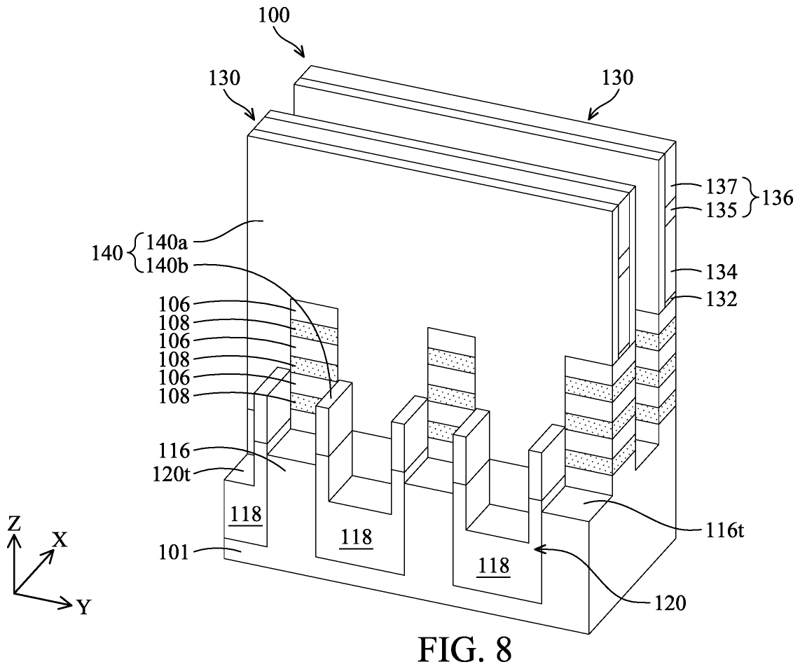

In FIG. 8, one or more etch processes are performed to recess the exposed second portions of the fin structures 112 not covered by the sacrificial gate structures 130 (and the portions of the gate spacer layer 138 formed on sidewalls of the sacrificial gate structures 130) and to remove portions of the gate spacer layer 138. The portions of the gate spacer layer 138 formed on sidewalls of the mask layer 136 may be also recessed. The one or more etch processes may include a dry etch, such as a RIE, NBE, or the like, and/or a wet etch, such as using tetramethyalammonium hydroxide (TMAH), ammonium hydroxide (NH₄OH). The one or more etch processes form gate spacers 140 including a first portion 140a formed on sidewalls of the sacrificial gate electrode layer 134 and second portions 140b formed on the second portions of the isolation regions 120. In some embodiments, the one or more etch processes also remove portions of the second portions of the isolation regions 120, as shown in FIG. 8. As a result, the top surface 120t of the second portion of the isolation region 120 is located at a level substantially below the top surface 116t of the well portion 116.

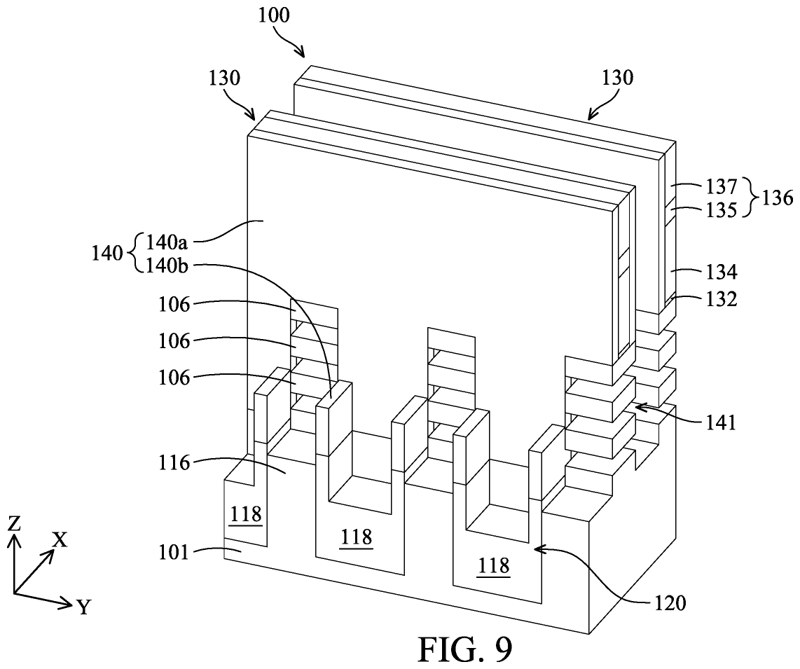

In FIG. 9, the second semiconductor layers 108 are removed. In some embodiments, the second semiconductor layers 108 include Ge, and the subsequently formed source/drain (S/D) regions include phosphorus doped silicon for n-type FET. The Ge in the second semiconductor layers 108 and the phosphorus in the S/D regions can inter-diffuse, which may induce high interfacial state density (Dit) on the first semiconductor layers 106. As a result, n-type device mobility may be degraded. Thus, in some embodiments, the second semiconductor layers 108 are removed prior to the formation of the S/D regions. In some embodiments, the second semiconductor layers 108 are completely removed, and openings 141 are formed between vertically adjacent first semiconductor layers 106, as shown in FIG. 9. The second semiconductor layers 108 may be removed by a selective etch process, such as a selective dry etch process, a selective wet etch process, or a combination thereof. The selective etch process does not substantially affect the gate spacers 140, the first semiconductor layers 106, the isolation regions 120, and the nitride layer 137.

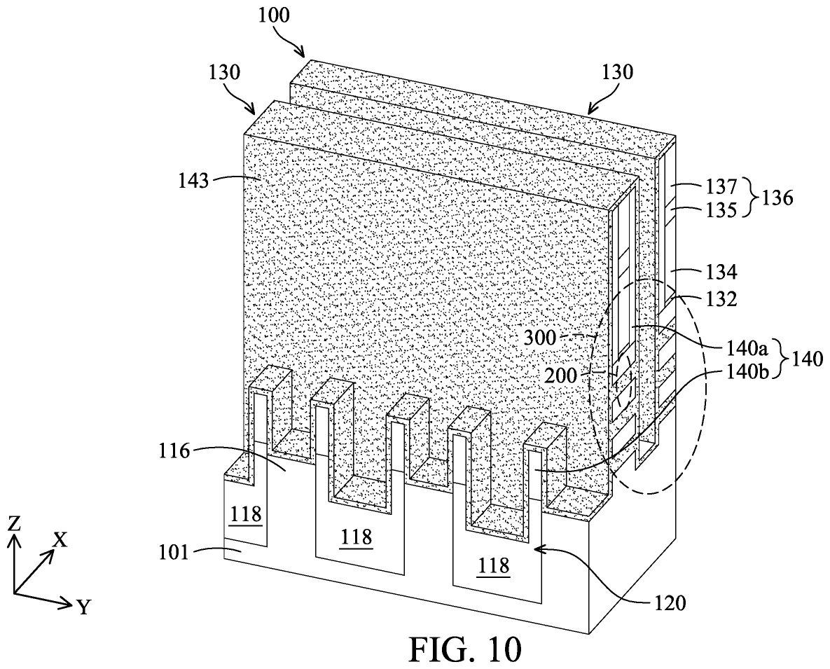

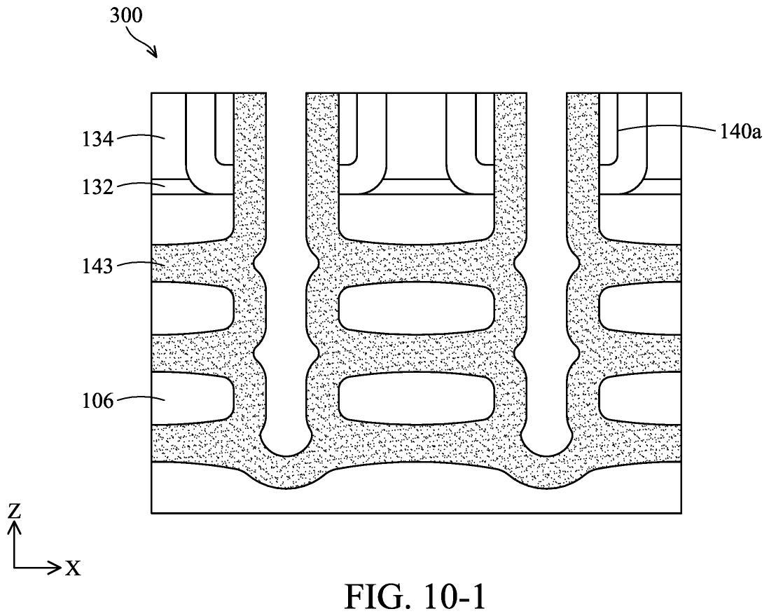

In FIG. 10, a dielectric material 143 is formed in the openings 141 and on the exposed surfaces of the semiconductor device structure 100. In some embodiments, the dielectric material 143 is an oxide, such as silicon dioxide, formed by the THOR process. In some embodiments, the THOR process is a thermal ALD process.

FIG. 10-1 is a cross-sectional side view of a portion 300 of the semiconductor device structure of FIG. 10, in accordance with some embodiments. As shown in FIG. 10-1, the dielectric material 143 is not only formed in the openings 141 but also formed on sidewalls of the sacrificial gate structures 130. In some embodiments, the gate spacer 140 includes two dielectric layers.

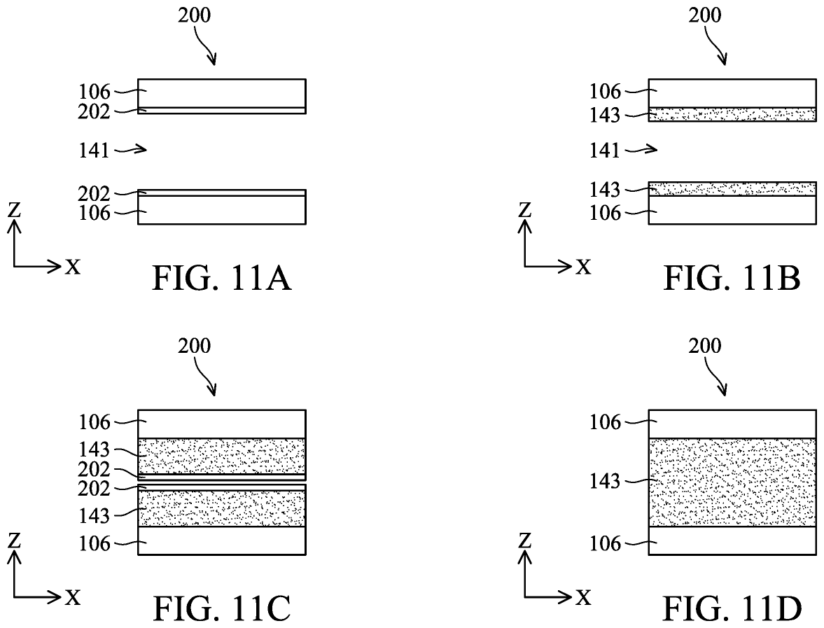

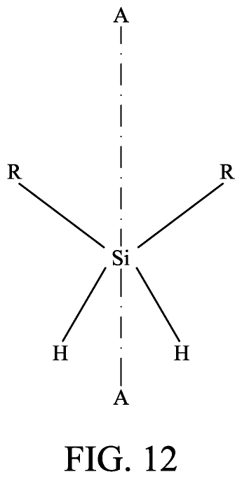

FIGS. 11A to 11D are cross-sectional side views of a portion 200 of the semiconductor device structure 100 of FIG. 10 at various stages of the thermal ALD process to form the dielectric material 143, in accordance with some embodiments. The portion 200 includes vertically adjacent first semiconductor layers 106, and the FIGS. 11A to 11F illustrate the ALD process to form the dielectric material 143 between the vertically adjacent first semiconductor layers 106 without a seam. The dielectric material 143 formed on side surfaces of the first semiconductor layers 106 is omitted in FIGS. 11A to 11D for clarity. As shown in FIG. 11A, a monolayer 202 is formed on the exposed surfaces of the first semiconductor layers 106. In some embodiments, the monolayer 202 is formed by exposing the first semiconductor layers 106 to a silicon-containing precursor at a processing temperature ranging from about 200 degrees Celsius to about 500 degrees Celsius, such as 250 degrees Celsius to about 400 degrees Celsius. The silicon-containing precursor may include any suitable silicon-containing material. In some embodiments, the silicon-containing precursor includes a material having the chemical structure shown in FIG. 12. As shown in FIG. 12, the silicon-containing precursor includes two R groups and two hydrogen atoms attached to the silicon atom. In some embodiments, each R group includes at least two carbons. The silicon-containing precursor may have a symmetrical chemical structure. For example, the appearance of the molecule shown in FIG. 12 does not change by rotating the molecule about a line A-A, which is an axis of symmetry through the silicon atom. With the silicon-containing precursor shown in FIG. 12, peroxy linkage, which is a bond between two oxygen atoms, are more likely to form in the dielectric material 143.

Referring back to FIG. 11A, the silicon-containing precursor may be flowed into a processing chamber in which the semiconductor device structure 100 is disposed therein, and the silicon-containing precursor has a first flow rate and a first duration. Next, the flow of the silicon-containing precursor is stopped, and a pumping process is performed to pump out any silicon-containing precursor in the processing chamber. After the pumping process, an oxygen-containing precursor is flowed into the processing chamber, and the oxygen-containing precursor reacts with the monolayer 202 to form the dielectric material 143, as shown in FIG. 11B. The processing temperature during the flowing of the oxygen-containing precursor may be the same as the processing temperature during the flowing of the silicon-containing precursor. In some embodiments, the processing temperature ranges from about 200 degrees Celsius to about 500 degrees Celsius, such as from about 250 degrees Celsius to about 400 degrees Celsius. The oxygen-containing precursor may include any suitable oxygen-containing material. In some embodiments, the oxygen-containing precursor includes ozone. The oxygen-containing precursor may be flowed into the processing chamber at a second flow rate substantially greater than the first flow rate of the silicon-containing precursor. In some embodiments, the second flow rate may be twice to 20 times the first flow rate, such as from about five times to about 10 times, or about 10 times to about 20 times. The oxygen-containing precursor may be flowed into the processing chamber for a second duration substantially longer than the first duration of the silicon-containing precursor. In some embodiments, the second duration may be twice to 20 times the first duration, such as from about five times to about 10 times, or about 10 times to about 20 times. In some embodiments, the second flow rate is about five times to about 10 times of the first flow rate, and the second duration is about five times to about 10 times of the first duration.

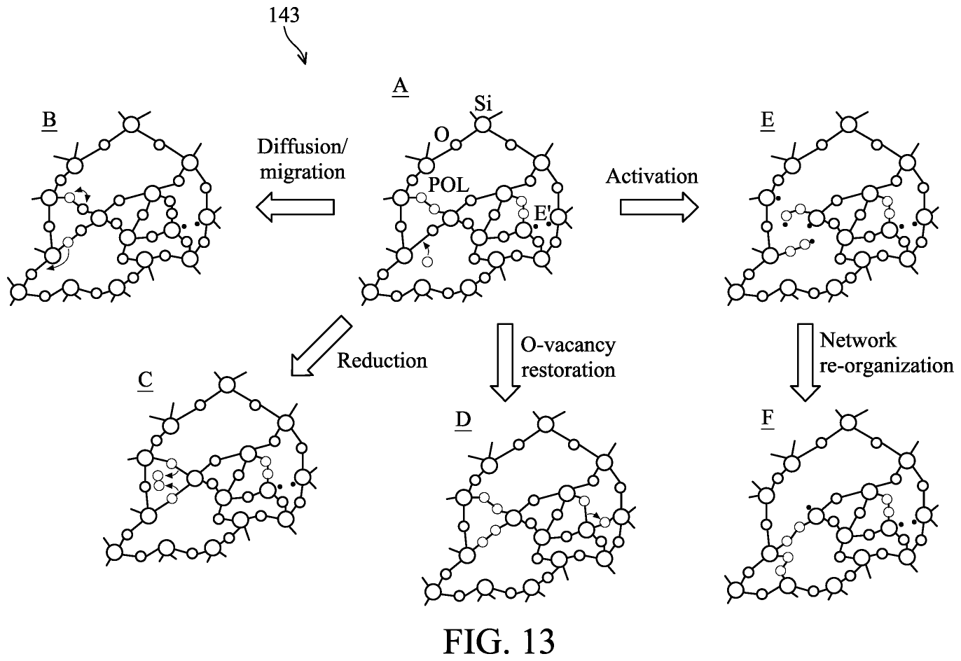

FIG. 13 illustrates various states of a compound formed by the thermal ALD process, in accordance with some embodiments. As shown in FIG. 13, the dielectric material 143 formed by the processes described in FIGS. 11A and 11B has states A, B, C, D, and E. In state A, the peroxy linkage (POL) is formed. In some embodiments, by using the silicon-containing precursor having the chemical structure shown in FIG. 12 and ozone as the oxygen containing precursor, POL is formed in state A. If the processing temperature of the thermal ALD process is greater than about 500 degrees Celsius, or if the deposition process is a plasma ALD process, reduction may occur, which changes the dielectric material 143 from state A to state C. As described above, in some embodiments, the flow rate of the oxygen-containing precursor is about twice to about 20 times, such as about 10 times to about 20 times, the flow rate of the silicon-containing precursor. In some embodiments, the duration of the exposure of the semiconductor device structure 100 to the oxygen-containing precursor is about twice to about 20 times, such as about 10 times to about 20 times, the duration of the exposure of the semiconductor device structure 100 to the silicon-containing precursor. In some embodiments, the flow rate of the oxygen-containing precursor is about five times to about 10 times the flow rate of the silicon-containing precursor, and the duration of the exposure of the semiconductor device structure 100 to the oxygen-containing precursor is about five times to about 10 times the duration of the exposure of the semiconductor device structure 100 to the silicon-containing precursor. These processing conditions favor the activation of the dielectric material 143 in state A, which results in state E, as shown in FIG. 13. The dielectric material 143 in state E is not stable and network re-organization is more likely to occur, leading to the dielectric material 143 in state F, as shown in FIG. 13. The changing of the states from state A to state E to state F can lead to a seamless dielectric material 143, which is described in detail in FIG. 11D.

If the flow rate of the oxygen-containing precursor is less than 10 times the flow rate of the silicon-containing precursor, the duration of the exposure to the oxygen-containing precursor is less than 10 times the duration of the exposure to the silicon-containing precursor, or a combination of the flow rate of the oxygen-containing precursor is less than 5 times the flow rate of the silicon-containing precursor and the duration of the exposure to the oxygen-containing precursor is less than 5 times the duration of the exposure to the silicon-containing precursor, reduction and/or O-vacancy restoration of the dielectric material 143 in state A are more favored. As a result, the dielectric material 143 may change from state A to state B and/or state D. On the other hand, if the flow rate of the oxygen-containing precursor is greater than 20 times the flow rate of the silicon-containing precursor, the duration of the exposure to the oxygen-containing precursor is greater than 20 times the duration of the exposure to the silicon-containing precursor, or a combination of the flow rate of the oxygen-containing precursor is greater than 10 times the flow rate of the silicon-containing precursor and the duration of the exposure to the oxygen-containing precursor is greater than 10 times the duration of the exposure to the silicon-containing precursor, the manufacturing cost is increased without significant advantage. In other words, the thermal ALD process using the silicon-containing precursor shown in FIG. 12, ozone as the oxygen-containing precursor, a faster oxygen-containing precursor flow rate and/or longer exposure duration to the oxygen-containing precursor, the formed dielectric material 143 has improved horizontal gap filling capability.

After exposing the semiconductor device structure 100 to the oxygen-containing precursor, the processing chamber is pumped again. The flowing of the silicon-containing precursor into the processing chamber and flowing of the oxygen-containing precursor into the processing chamber (with pumping of the processing chamber in between) are considered a cycle of the thermal ALD process. After multiple cycles, the dielectric material 143 fills the opening 141 between vertically adjacent first semiconductor layers 106, as shown in FIGS. 11C and 11D. As shown in FIG. 11C, the monolayer 202 is formed on the dielectric material 143, and a gap is formed between the portion of the monolayer 202 formed over a bottom first semiconductor layer 106 and the portion of the monolayer 202 formed under a top first semiconductor layer 106. The gap is substantially small. In some embodiments, the gap ranges from about 0.1 nm to about 0.3 nm. In some embodiments, the gap is less than the bond length of Si—O—O—Si. Next, the oxygen-containing precursor is flowed into the processing chamber and reacts with the monolayer 202 to form the dielectric layer 143. As described above, the processing conditions favors the dielectric material 143 changes from state A to state E to state F. As shown in FIG. 13, Si—O—O—Si in state A is broken to dangling Si bonds and peroxy radicals, as shown in state E. Due to the small gap between the portions of the monolayer 202, the peroxy radical of the portion of the monolayer 202 formed over the bottom first semiconductor layer 106 may bond with the dangling Si bond of the portion of the monolayer 202 formed under the top first semiconductor layer 106, which is changing the dielectric material 143 from state E to state F. As a result, the gap is filled and the dielectric material 143 seamlessly fills the openings 141. In addition, the dielectric material 143 formed by the processes described in FIGS. 11A to 11D has a wet etch rate greater than about 100 Angstroms per minute (using 1:100 diluted HF solution).

In some embodiments, the thermal ALD process includes a plurality of cycles to form the dielectric material 143. A first number of cycles are performed under a first processing conduction, and the second number of cycles are performed under a second processing condition different from the first processing condition. The second processing condition may be the processing condition described in FIGS. 11A to 11D, and the first processing condition may lead to fast deposition and/or less precursor utilized. For example, the first processing condition may include flowing the silicon-containing precursor and the oxygen-containing precursor at the substantially the same flow rate and/or for the same duration. In some embodiments, the flow rate of the silicon-containing precursor in the first processing condition is the same as the flow rate of the silicon-containing precursor in the second processing condition, and the flow rate of the oxygen-containing precursor in the second processing condition is about twice to about 20 times the flow rate of the oxygen-containing precursor in the first processing condition. In some embodiments, the duration of exposing to the silicon-containing precursor in the first processing condition is the same as the duration of exposing to the silicon-containing precursor in the second processing condition, and the duration of exposing to the oxygen-containing precursor in the second processing condition is about twice to about 20 times the duration of exposing to the oxygen-containing precursor in the first processing condition. The processing temperature in the first processing condition may be greater than 500 degrees Celsius. The silicon-containing precursor in the first processing condition may be any suitable silicon-containing material, such as silane, disilane, dichlorosilane, trichlorosilane, and the oxygen-containing precursor may be any suitable oxygen-containing material, such as oxygen gas, NO₂, CO₂. In some embodiments, about 60 percent to about 90 percent of the plurality of cycles are performed under the first processing condition, and about 10 percent to about 40 percent of the plurality of cycles are performed under the second processing condition. The cycles performed with the second processing condition are performed after the cycles performed with the first processing condition. In other words, the thermal ALD process includes performing a first plurality of cycles under the first processing condition to form the dielectric material 143 between vertically adjacent first semiconductor layers 106, and a gap is formed between the portions of the dielectric material 143 formed on the top and bottom first semiconductor layers 106. The thermal ALD process further includes performing a second plurality of cycles under the second processing condition to fill the gap with the dielectric material 143, and the result dielectric material 143 formed between the vertically adjacent first semiconductor layers 106 is seamless. In some embodiments, the first plurality of cycles include a first number of cycles, the second plurality of cycles include a second number of cycles, and the first number of cycles is about 1.5 times to about 9 times second number of cycles.

In some embodiments, a low temperature thermal ALD process is performed to form the dielectric material 143. The dielectric material 143 as deposited includes SiO₂, with a ratio of silicon to oxygen being less than about 2. The deposition temperature ranges from about 200 degrees Celsius to about 500 degrees Celsius, and the deposition rate in growth per cycle (GPC) ranges from about 0.01 Angstroms per cycle to about 10 Angstroms per cycle or from about 0.1 Angstroms per minute to about 20 Angstroms per minute. The low temperature thermal ALD process may be a single chamber ALD or batch type ALD. In some embodiments, organic silicon-containing precursors and oxygen-containing precursors are used in the low temperature thermal ALD process. The oxygen-containing precursor may include O₂ radical and/or O₃, which may achieve self-limited effect if the process temperature is well controlled. The dielectric material 143 deposited by the low temperature thermal ALD process may have a wet etch rate (WER) of greater than 100 Angstroms per minute, such as from about 100 Angstroms per minute to about 800 Angstroms per minute, in 1:100 diluted hydrofluoric acid and a density ranging from about 1.5 g/cm³ to about 2.3 g/cm³. The dielectric material 143 may have a —OH peak feature at 3400±100 using Fourier-transform infrared spectroscopy (FTIR). The dielectric material 143 may have a leakage greater than about 1E⁻⁶ A/cm² at 2 MV/cm. During the deposition of the dielectric material 143, the silicon consumption of the first semiconductor layers 106 may range from about 2 Angstroms to about 10 Angstroms due to oxidation. The dielectric material 143 may include carbon and nitrogen having a concentration of less than 1E4 atoms and hydrogen and hydroxide having a concentration of greater than 1E4 atoms. The roughness of the dielectric material 143 may be less than 0.5 Angstroms (RMS) or less than 5 Angstroms (Rmax).

In some embodiments, a hybrid ALD process is performed to form the seamless dielectric material 143 between vertically adjacent first semiconductor layers 106. The hybrid ALD process includes a plasma stage followed by a thermal stage. For example, the plasma stage includes a first plurality of cycles performed as a plasma enhanced ALD (PEALD) process, and the thermal stage includes a second plurality of cycles performed as a thermal ALD process. The thermal ALD process may be the thermal ALD process described in FIGS. 11A to 11D. The PEALD process may be performed at a substantially lower processing temperature, such as from about 50 degrees Celsius to about 100 degrees Celsius. The silicon-containing precursor and the oxygen-containing precursor in the PEALD may be the same as the silicon-containing precursor and the oxygen-containing precursor of the first processing condition described above, and the silicon-containing precursor and the oxygen-containing precursor may be activated by a plasma, such as capacitively coupled plasma (CCP), inductively coupled plasma (ICP), transformer coupled plasma (TCP). Similar to the first processing condition, the plasma stage of the hybrid ALD utilizes less precursors and is faster compared to the second processing condition of the thermal ALD (or the thermal stage of the hybrid ALD).

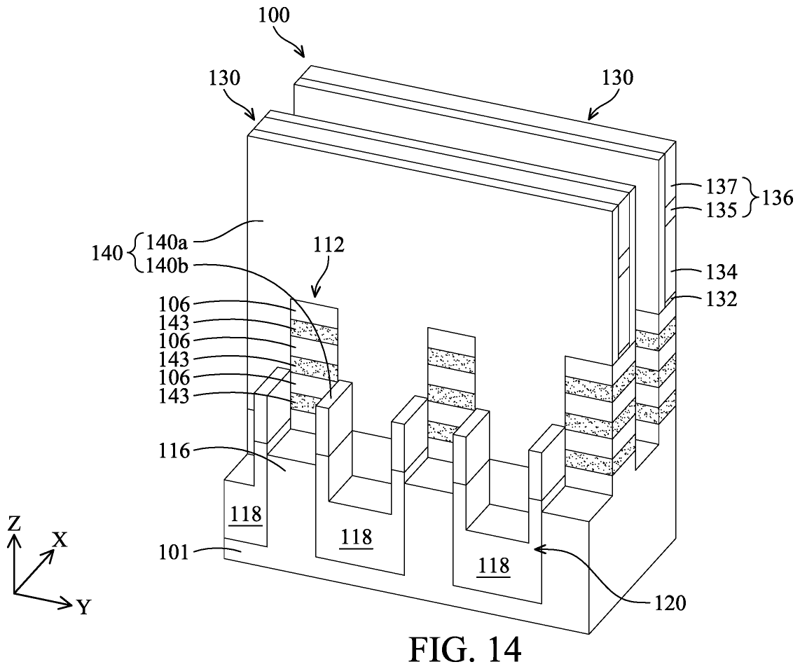

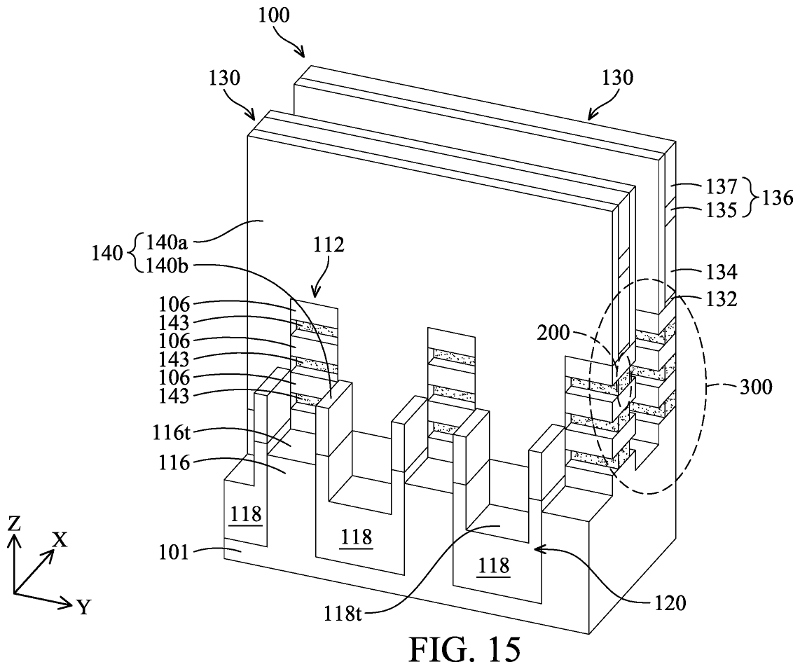

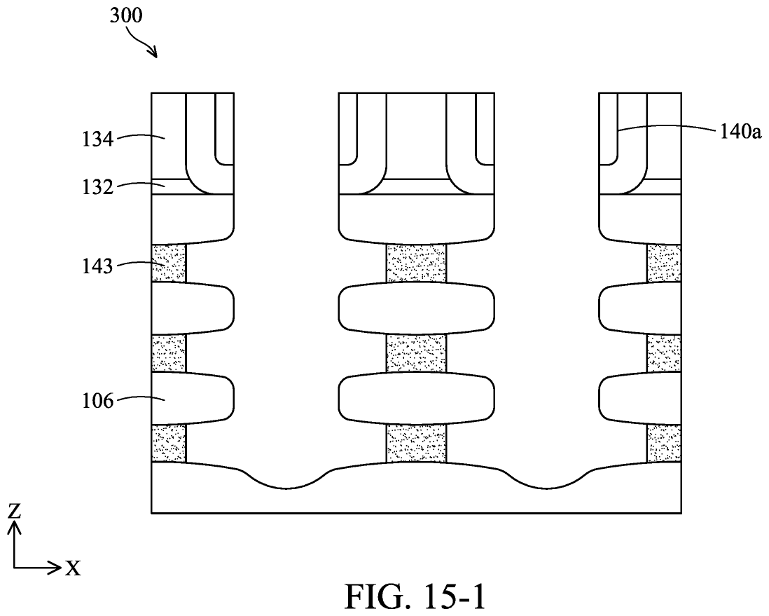

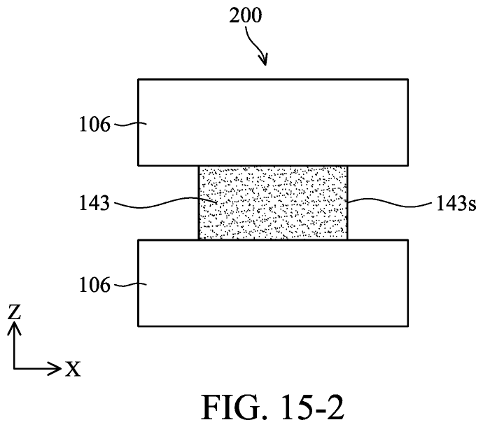

FIGS. 14 to 20 are perspective views of various stages of manufacturing the semiconductor device structure 100, in accordance with some embodiments. As shown in FIG. 14, an etch back process is performed to remove portions of the dielectric material 143 other than the portions of the dielectric material 143 formed in the openings 141. In some embodiments, the etch back process is an anisotropic etching process. At this stage, edge portions of the dielectric material 143 and edge portions of the first semiconductor layers 106 have substantially flat surfaces which may be flush with corresponding first portions 140a of the gate spacers 140, as shown in FIG. 14. As shown in FIG. 15, edge portions of the dielectric material 143 are removed horizontally along the X direction. In other words, the dielectric material 143 is recessed along the X direction. The removal of the edge portions of the dielectric material 143 forms cavities. In some embodiments, the edge portions of the dielectric material 143 are removed by a selective wet etch process using etchants such as HF and NH₃, DHF solution, or deionized water with ozone and DHF solution.

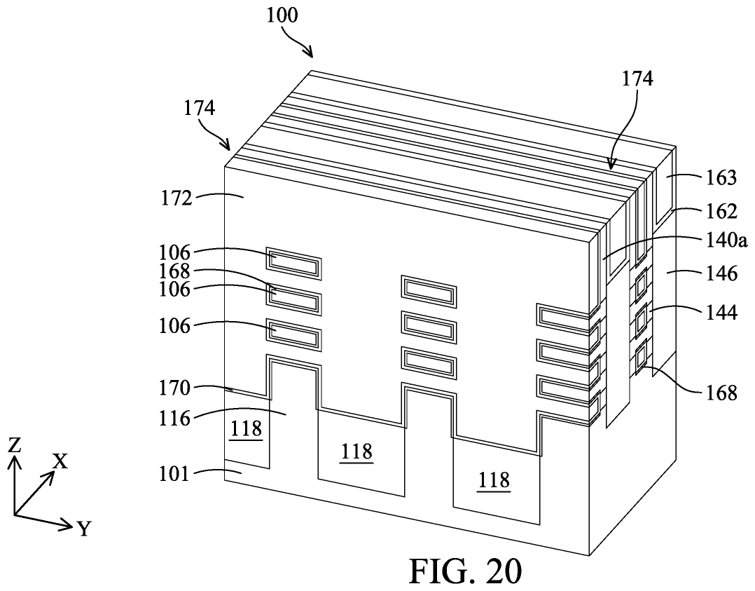

FIG. 15-1 is a cross-sectional side view of a portion 300 of the semiconductor device structure of FIG. 15, in accordance with some embodiments. As shown in FIG. 15-1, the edge portions of the dielectric material 143 are removed, and cavities are formed between vertically adjacent first semiconductor layers 106. FIG. 15-2 is a cross-sectional side view of a portion 200 of the semiconductor device structure 100 of FIG. 15, in accordance with some embodiments. As shown in FIG. 15-2, the dielectric material 143 include side surfaces 143s after the horizontal recess. Because the dielectric material 143 is formed seamlessly between adjacent first semiconductor layers 106, the side surfaces 143s are substantially linear. If a seam is formed in the dielectric material 143, the side surfaces 143s may be concave, which may lead to electrical shortage between the gate electrode layer 172 (FIG. 20) and the S/D regions 146 (FIG. 20).

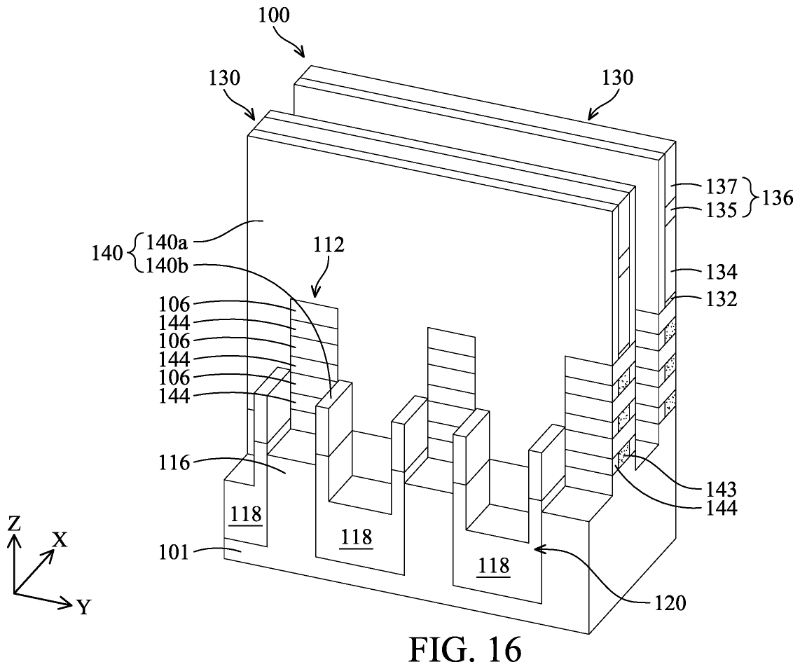

After removing edge portions of the dielectric material 143, a dielectric layer is deposited in the cavities to form dielectric spacers 144, as shown in FIG. 16. The dielectric spacers 144 may be made of a dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The dielectric material 143 is capped between the dielectric spacers 144 along the X direction, as shown in FIG. 13. In some embodiments, the dielectric spacers 144 and the dielectric material 143 include different materials having different etch selectivity.

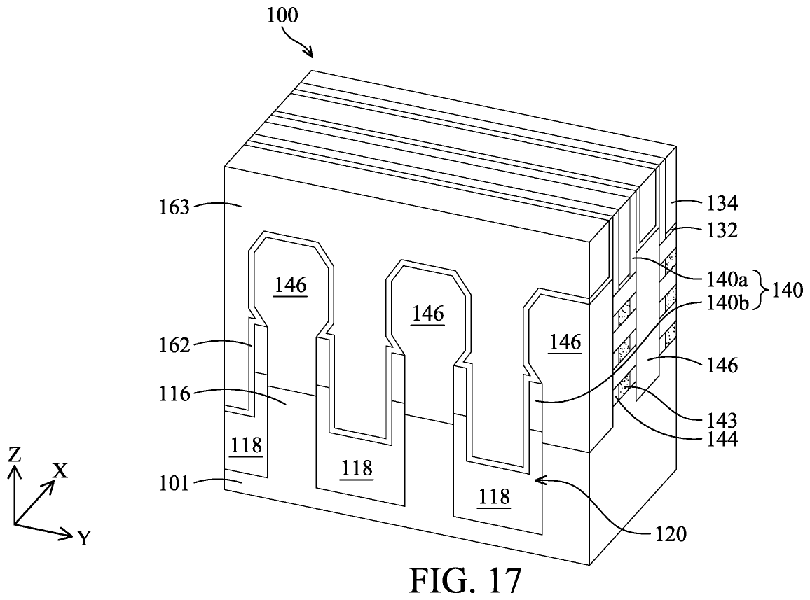

As shown in FIG. 17, source/drain (S/D) regions 146 are formed from the well portion 116. In some embodiments, the S/D regions 146 may grow both vertically and horizontally to form facets, which may correspond to crystalline planes of the material used for the well portion 116. In this disclosure, a source region and a drain region are interchangeably used, and the structures thereof are substantially the same. Furthermore, source/drain region(s) may refer to a source or a drain, individually or collectively dependent upon the context. In some embodiments, the S/D regions 146 are n-type S/D epitaxial features and may be made of one or more layers of Si, SiP, SiC and SiCP for n-channel FETs. In some embodiments, the S/D regions 146 are p-type epitaxial features and may be made of one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. As described above, the second semiconductor layers 108 (FIG. 8) are removed during the formation of the S/D regions 146. As a result, the source of Ge is removed prior to the formation of the S/D regions 146, and Dit is improved.

As shown in FIG. 17, a contact etch stop layer (CESL) 162 is conformally formed on the exposed surfaces of the semiconductor device structure 100. The CESL 162 covers the sidewalls of the first portion 140a of the gate spacers 140 and is disposed on the second portion 140b of the gate spacers 140 and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134, as shown in FIG. 17. The planarization process may be any suitable process, such as a CMP process. The planarization process removes portions of the ILD layer 163 and the CESL 162 disposed on the sacrificial gate stacks 130. The planarization process may also remove the mask structure 136.

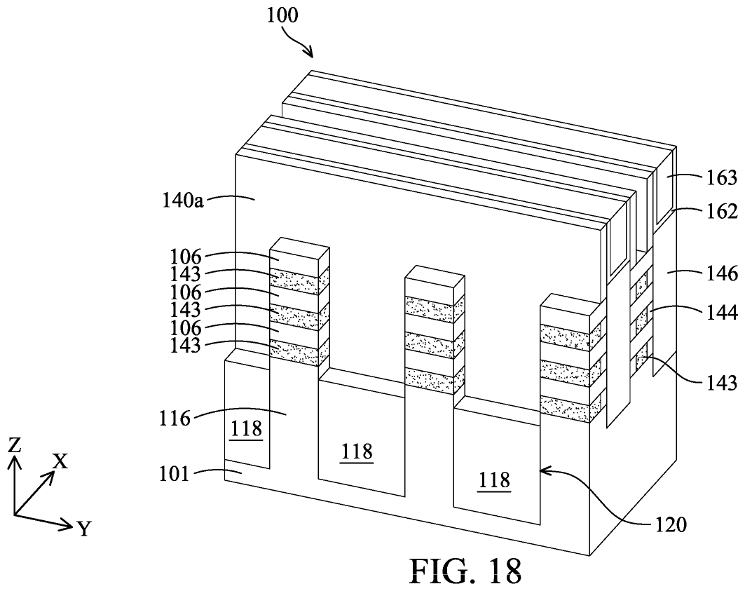

As shown in FIG. 18, the sacrificial gate electrode layer 134 and the sacrificial gate dielectric layer 132 are removed, exposing a portion of the top surface of the topmost first semiconductor layer 106. The first portions of the isolation regions 120 are also exposed. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 140, the ILD layer 163, and the CESL 162.

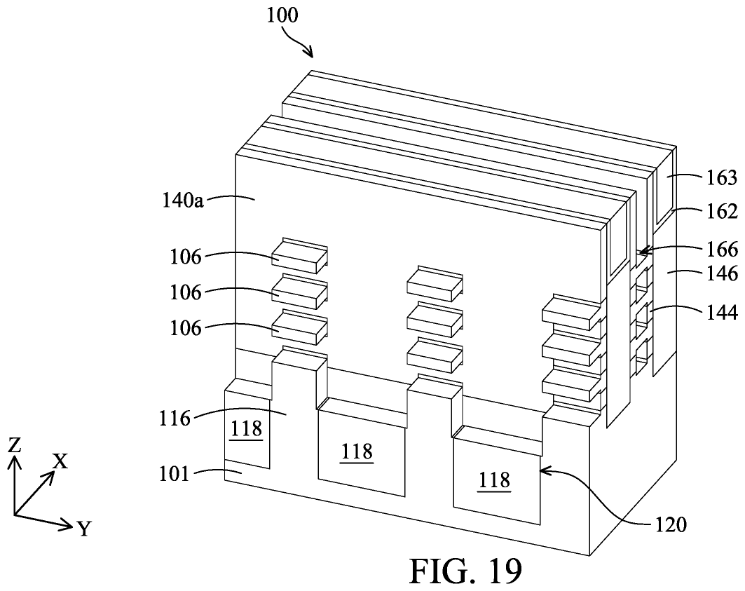

As shown in FIG. 19, the dielectric material 143 is removed. The dielectric material 143 may be removed by any suitable process. In some embodiments, the dielectric material 143 is removed by a selective etch process. The selective etch process removes the dielectric material 143 between the first semiconductor layers 106 but does not remove the first semiconductor layers 106, the ILD layer 163, the CESL 162, and the gate spacers 140. The portion of each first semiconductor layer 106 not covered by the dielectric spacers 144 may be exposed after the removal of the dielectric material 143. Each first semiconductor layer 106 may be a nanostructure channel.

As shown in FIG. 20, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) 168 is formed between the gate dielectric layer 170 and the exposed surfaces of the first semiconductor layers 106. The IL 168 may include an oxide, such as silicon oxide, and may be formed as a result of a clean process. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed.

Embodiments of the present disclosure provide a method for forming a semiconductor device structure 100. In some embodiments, the method is a THOR process. The THOR process may be a thermal ALD process, a thermal ALD process with different processing conditions for different number of cycles, or a hybrid ALD process. Some embodiments may achieve advantages. For example, the dielectric material 143 formed by the THOR process between vertically adjacent first semiconductor layers 106 is seamless.

An embodiment is a method. The method includes removing a first semiconductor layer disposed between a second semiconductor layer and a third semiconductor layer and performing an oxide refill process to form a seamless dielectric material between the second and third semiconductor layers. The oxide refill process includes exposing the second and third semiconductor layers to a silicon-containing precursor for a first duration to form a monolayer, the silicon-containing precursor has a first flow rate and a chemical structure of:

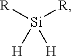

and each R group includes at least two carbons. The oxide refill process further includes exposing the monolayer to an oxygen-containing precursor for a second duration to form the seamless dielectric material, the oxygen-containing precursor has a second flow rate, the second flow rate is about twice to about 20 times the first flow rate, and the second duration is about twice to about 20 times the first duration.

Another embodiment is a method. The method includes forming a fin structure from a substrate, and the fin structure includes a stack of semiconductor layers including alternating first and second semiconductor layers. The method further includes forming a sacrificial gate stack on a first portion of the fin structure, recessing a second portion of the fin structure, removing the second semiconductor layers disposed under the sacrificial gate stack to form openings between vertically adjacent first semiconductor layers, and performing an atomic layer deposition process to form a seamless dielectric material in the openings. The atomic layer deposition process includes performing a first plurality of cycles, each cycle including flowing a first silicon-containing precursor into a processing chamber at a first flow rate for a first duration and flowing a first oxygen-containing precursor into the processing chamber at a second flow rate for a second duration, and then performing a second plurality of cycles, each cycle including flowing a second silicon-containing precursor different from the first silicon-containing precursor into the processing chamber at a third flow rate for a third duration and flowing a second oxygen-containing precursor into the processing chamber at a fourth flow rate for a fourth duration.

A further embodiment is a method. The method includes forming a fin structure from a substrate, and the fin structure includes a stack of semiconductor layers including alternating first and second semiconductor layers. The method further includes recessing a portion of the fin structure to expose a well portion of the fin structure, removing the second semiconductor layers to form openings between vertically adjacent first semiconductor layers, and performing a hybrid atomic layer deposition process to form a seamless dielectric material in the openings. The hybrid atomic layer deposition process includes performing a plasma enhanced atomic layer deposition process at a first temperature, and then performing a thermal atomic layer deposition process at a second temperature substantially greater than the first temperature. The method further includes forming a source/drain region from the well portion, removing the seamless dielectric material, and forming a gate electrode layer surrounding exposed portions of the first semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
removing a first semiconductor layer disposed between a second semiconductor layer and a third semiconductor layer; and
performing an oxide refill process to form a seamless dielectric material between the second and third semiconductor layers, comprising:
exposing the second and third semiconductor layers to a silicon-containing precursor for a first duration to form a monolayer, wherein the silicon-containing precursor has a first flow rate and a chemical structure of: 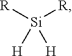
wherein each R group includes at least two carbons;
exposing the monolayer to an oxygen-containing precursor for a second duration to form the seamless dielectric material, wherein the oxygen-containing precursor has a second flow rate, the second flow rate is about twice to about 20 times the first flow rate, and the second duration is about twice to about 20 times the first duration.

2. The method of claim 1, wherein the second flow rate is about 10 times to about 20 times the first flow rate, or the second duration is about 10 times to about 20 times the first duration.

3. The method of claim 2, wherein the second flow rate is about five times to about 10 times the first flow rate, and the second duration is about five times to about 10 times the first duration.

4. The method of claim 1, wherein the oxygen-containing precursor comprises ozone.

5. The method of claim 1, wherein a processing temperature of the oxide refill process ranges from about 200 degrees Celsius to about 500 degrees Celsius.

6. The method of claim 1, wherein the first semiconductor layer comprises SiGe, and the second and third semiconductor layers each comprises Si.

7. A method, comprising:
forming a fin structure from a substrate, wherein the fin structure comprises a stack of semiconductor layers comprising alternating first and second semiconductor layers;
forming a sacrificial gate stack on a first portion of the fin structure;
recessing a second portion of the fin structure;
removing the second semiconductor layers disposed under the sacrificial gate stack to form openings between vertically adjacent first semiconductor layers; and
performing an atomic layer deposition process to form a seamless dielectric material in the openings, comprising:
performing a first plurality of cycles, each cycle including flowing a first silicon-containing precursor into a processing chamber at a first flow rate for a first duration and flowing a first oxygen-containing precursor into the processing chamber at a second flow rate for a second duration; and then
performing a second plurality of cycles, each cycle including flowing a second silicon-containing precursor different from the first silicon-containing precursor into the processing chamber at a third flow rate for a third duration and flowing a second oxygen-containing precursor into the processing chamber at a fourth flow rate for a fourth duration.

8. The method of claim 7, wherein the first flow rate and the second flow rate are substantially the same.

9. The method of claim 8, wherein the third flow rate and the first flow rate are substantially the same.

10. The method of claim 9, wherein the fourth flow rate is substantially greater than the second flow rate.

11. The method of claim 7, wherein the first duration and the second duration are substantially the same.

12. The method of claim 11, wherein the third duration and the first duration are substantially the same.

13. The method of claim 12, wherein the fourth duration is substantially greater than the second duration.

14. The method of claim 7, further comprising removing edge portions of the seamless dielectric material to form cavities.

15. The method of claim 14, further comprising depositing dielectric spacers in the cavities.

16. The method of claim 7, wherein the first plurality of cycles comprise a first number of cycles, and the second plurality of cycles comprise a second number of cycles substantially less than the first number of cycles.

17. A method, comprising:
forming a fin structure from a substrate, wherein the fin structure comprises a stack of semiconductor layers comprising alternating first and second semiconductor layers;
recessing a portion of the fin structure to expose a well portion of the fin structure;
removing the second semiconductor layers to form openings between vertically adjacent first semiconductor layers;
performing a hybrid atomic layer deposition process to form a seamless dielectric material in the openings, comprising:
performing a plasma enhanced atomic layer deposition process at a first temperature; and then
performing a thermal atomic layer deposition process at a second temperature substantially greater than the first temperature;
forming a source/drain region from the well portion;
removing the seamless dielectric material; and
forming a gate electrode layer surrounding exposed portions of the first semiconductor layers.

18. The method of claim 17, wherein the first temperature ranges from about 50 degrees Celsius to about 100 degrees Celsius, and the second temperature ranges from about 200 degrees Celsius to about 500 degrees Celsius.

19. The method of claim 17, wherein the plasma enhanced atomic layer deposition process comprises a first number of cycles, and the thermal atomic layer deposition process comprises a second number of cycles substantially less than the first number of cycles.

20. The method of claim 19, wherein the first number of cycles is about 1.5 times to about 9 times the second number of cycles.
